(19) United States
(12) Patent Application Publication
(10) Pub. No.: US 2003/0073008 A1
(43) Pub. Date: Apr. 17, 2003

(54) Method for certifying a newly-made photomask

(76) Inventors: Ming-Yu Lin, Hsinchu (TW); Wei Ming Chen, Hsinchu (TW); Chung-Hsien Chou, Hsinchu (TW); Man-Tang Wu, Hsinchu (TW)

Correspondence Address: J.C. Patents, Inc., 4 Venture, Suite 250, Irvine, CA, 92618, US

(21) Appl. No.: 10/020,699

(22) Filed: Oct. 30, 2001

(30) Foreign Application Priority Data
Oct. 15, 2001 (TW) 90125363

(51) Int. Cl. G03F 9/00

(52) U.S. Cl. 430/5; 430/312; 430/314

(57) ABSTRACT

A method for certifying a newly-made photomask is disclosed. A wafer is provided first. Then, a pattern of a newly-made photomask is transferred onto the wafer in order to form a first pattern thereon, followed by transferring a pattern of an original photomask onto the wafer to form a second pattern. Subsequently, a comparison between the first pattern and the second pattern is made by using an optical inspector for examining the correctness of the newly-made photomask.

### CROSS-REFERENCE TO RELATED APPLICATION

This application claims the priority benefit of Taiwan application serial no. 90125363, filed Oct. 15, 2001.

### BACKGROUND OF THE INVENTION

1. Field of Invention

The present invention relates to a method for examining a newly-made photomask. More particularly, the present invention relates to a method for examining a newly-made photomask by comparing it with an original photomask using an optical inspector.

2. Description of Related Art

Photolithography is one of the most important processes in semiconductor industry. Many structures, such as layer patterns and doping regions, in metal oxide semiconductor (MOS) device are determined by photolithography. As integration increases, the dimensions in the design for circuit devices must be further minimized, thus the developments of photolithographic technology would determine whether a line width can be shrunk.

The correctness of a photomask is critical for perfectly performing a photolithographic process. If the mask pattern is not correct, a transferred pattern to the photosensitive material formed on a wafer is also incorrect and therefore the yield is reduced. Moreover, for producing any amount of identical semiconductor devices, it of course needs to increase production lines and create many new masks. These new masks are made using the specifications of the original masks, therefore the new masks are identical to those original ones. If the patterns on the new masks are different from those on the original masks, the products produced by the new masks are possibly defective. Therefore, it is rather important how to examine the correctness of a newly-made photomask before it is used for performing a photolithographic process.

However, there are not any suitable methods for examining newly-made photomasks in semiconductor industry nowadays. In general, the newly-made masks are directly subjected to production lines for producing new products, and then the errors existing in the newly-made masks can be found only by comparing the new products with the original ones in the production lines. It usually takes more than two months for this examination procedure, and in fact the newly-made masks are still not certified as correct because of many issues with respect to the circuit design.

In conventional method for examining new-made photomasks, the patterns of a new mask is transferred to a wafer first. During the examination, one die on the wafer is selected for comparing patterns with its neighboring dies, respectively. Since each of the die patterns on the wafer is transferred from that of the new mask, the errors existing in the patterns of the new mask cannot be found as the selected die and its neighbors have the same defect(s) in pattern. By the conventional examining method i.e. from producing new products by using the new mask to find out the errors in the mask, it has a great deal of waste in cost, because not only the correctness of the mask cannot be utterly certified, but the time consumed in examination is great. Furthermore, the conventional method can be used merely to compare the masks in the same generation, but not be used to compare those masks in different generations.

### SUMMARY OF THE INVENTION

Therefore, it is an object of the present invention to provide an examination method for newly-made photomasks that can certify the correctness of newly-made masks quickly in order to solve the drawbacks in the prior art.

It is another object of the present invention to provide an examination method for newly-made photomasks that can examine the photomasks in different generations.

It is a further object of the present invention to provide an examination method for newly-made photomasks that can certify the correctness of newly-made photomasks before they are used to produce any amount of new products and saves the cost.

According to the objects described above, the present invention provides an examination method for newly-made photomasks comprising the following steps. First, a wafer is provided on which a first pattern is formed by transferring a pattern of a newly-made mask onto the wafer. Subsequently, a second pattern is formed on the wafer by transferring a pattern of an original mask onto the wafer. The first pattern and the second pattern are compared to certify the correctness of the newly-made photomask.

As described in an embodiment of the present invention, the above-described patterns transferred from the new mask and the original mask are formed on a photoresist layer of the same wafer, respectively. The pattern of the new mask is transferred to a plurality of first exposure shots (exposure areas) on the wafer while the pattern of the original mask is transferred to a plurality of second exposure shots (exposure areas) and to a plurality of third exposure shots (exposure areas) on the wafer. The first shots are located between the second and third shots, and the first, second, and third shots are aligned in columns, respectively. While comparing these patterns, one of the first shots and its two neighboring ones in the second and third shots are selected for comparing. If there are not found any differences among those selected shots, it can be certified that the newly-made photomask is correct. If any differences are shown, these differences must be further examined in order to ensure whether they are attributed to the pattern of the newly-made photomask.

In the present invention, the patterns of the newly-made masks and the original masks are transferred to the same wafer, and the new masks are examined by comparing them with the original masks (correct masks) in an optical inspector. The correctness of the new masks can be examined effectively and rapidly in three days. From the present invention, the cost for production can be saved since the correctness of the new masks can be certified quickly before the new masks are subjected to produce products.

In the present invention, the patterns of the new masks and the original masks are compared by the manner of shot to shot in the optical inspector, thus test keys located on the edges of the photomasks can also be compared for examining the correctness of the whole masks. Unlike the conventional method that examines the photomask by the manner of die to die, the present invention is more effective and rapid.

In addition, from the present invention, the examination can be conducted between a newly-made photomask and an original photomask in different generations as well as in the same generation, for example, an I-line photomask can be used to certify a deep-UV photomask. Similarly, it also can obtain a relatively excellent result as a deep-UV photomask is used to examine an I-line photomask.

According to the objects described above, the present invention provides another examination method for newly-made photomasks comprising the following steps. First, a wafer is provided over which a material layer and a first photoresist layer are formed in sequence. The first photoresist layer is exposed by using a newly-made photomask, followed by developing the first photoresist layer so as to transfer the pattern of the newly-made photomask thereon. Subsequently, by using the patterned first photoresist layer as a mask, the material layer is etched to form a first pattern therein and removing the first photoresist layer follows. Next, a second photoresist layer is formed over the wafer. By using an original photomask, the second photoresist layer is exposed and developed so that the pattern of the original photomask is transferred therein. The material layer is etched to form a second pattern therein by using the patterned second photoresist layer as a mask, followed by removing the first photoresist layer. Consequently, the first pattern and the second pattern are compared to certify the correctness of the newly-made photomask.

As described in an embodiment of the present invention, the patterns of the new photomask and the original one are transferred to a material layer formed over the wafer in sequence. The optical inspector is used to conduct the comparison between the patterns of the new photomask and the original one formed in the material layer in order to examine the new photomask. By the present invention, the correctness of a newly-made photomask can be certified effectively and rapidly in three days. The correctness of new masks can be certified quickly before the new masks are subjected to produce any amount of products and the production cost therefore is saved.

In the present invention, an optical inspector is used to conduct an examination procedure, during which the patterns of the new masks and the original masks are compared according to the exposure shots formed in the material layer. Thus, test keys located on the edges of the photomasks can also be compared for examining the correctness of the whole masks. Unlike the conventional method that examines the photomask by the manner of die to die, the present invention is more effective and rapid.

In addition, by the present invention, the examination can be conducted between a newly-made photomask and an original photomask in different generations as well as in the same generation, for example, an I-line photomask can be used to certify a deep-UV photomask. Similarly, it also can obtain a relatively excellent result as a deep-UV photomask is used to examine an I-line photomask

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a schematic view, illustrating the method for examining a newly-made photomask according to the first preferred embodiment of the present invention;

FIG. 2 is a schematic view, illustrating the method for examining a newly-made photomask according to the second preferred embodiment of the present invention;

FIGS. 3A through 3D are schematic, cross-sectional views along line II-II′ showed in FIG. 2, illustrating successive steps according to the second preferred embodiment of the present invention; and

FIG. 4 is a schematic view, illustrating the method for examining a newly-made photomask according to the present invention.

### DESCRIPTION OF THE PREFERRED EMBODIMENTS

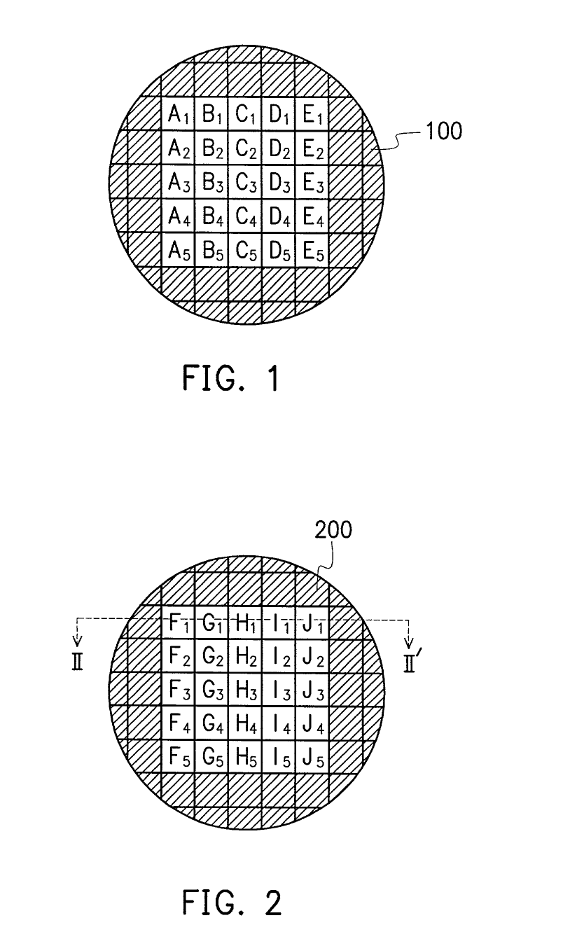

In the first preferred embodiment of the present invention, a method for examining the photomasks in the same generation is disclosed. Referring to FIG. 1, a photoresist layer is formed over a wafer 100. Patterns of a newly-made photomask are transferred individually onto exposure shots C1 to C5 on the wafer 100. Subsequently, patterns of an original photomask are transferred individually onto exposure shots A1 to A5 and B1 to B5 on the wafer 100 at the left side of the exposure shots C1 to C5, and patterns of an original photomask are transferred individually onto exposure shots D1 to D5 and E1 to E5 on the wafer 100 at the right side of the exposure shots C1 to C5. The wafer 100 is placed in an optical inspector and the patterns of the new photomask and the original photomask are compared in order to certify the new photomask. The optical inspector is a KLA optical inspector, for example. The exposure shots A1 to A5 and B1 to B5 are aligned with columns, respectively, at the left side of the Exposure shots C1 to C5, while the exposure shots D1 to D5 and E1 to E5 are aligned with columns, respectively, at the right side of the Exposure shots C1 to C5. Therefore, the arrangement of the shot columns from left to right in sequence is exposure shots A1 to A5, B1 to B5, C1 to C5, D1 to D5, and E1 to E5, as shown in FIG. 1.

In actual examination, for example, the shot C1 is compared with its adjacent shot B1 and the shot B1 is compared with its adjacent shot A1, to find out any differences existing among them, in the other side, the shot D1 is compared with the shots C1 and E1, respectively, to find out any differences existing among them. If there are no differences among those compared shots, it can be certified that the newly-made photomask is correct. If any differences are shown, these differences must be further examined in order to ensure whether they result from errors on the pattern of the newly-made photomask.

In the examination method described above, the patterns of the newly-made photomask and the original photomask are compared with the whole exposure shots, therefore it is easier to examine whether the new-made photomask is defective or not. This is because some patterns are located on the edge but not in the dies of the mask, for example, test keys are usually located on the cutting lines of a photomask. Therefore, if the newly-made photomask is examined by just comparing with the neighboring dies, the test keys located on the edge of the newly-made mask cannot be certified that they are the same. In the present invention, the newly-made photomask and the original photomask are compared with the whole exposure shots so that the test key can be examine to certify the correctness of the whole newly-made photomask.

In the second preferred embodiment of the present invention, the photomasks for different generations can be examined each other. For example, an I-line photomask can be used to certify a DEEP-UV mask while a DEEP-UV mask can be used to certify an I-line photomask. The examination for the masks between different generations is more complicated because of the distinct scale-down ratios for patterns of photomasks, thus the comparison between patterns of the photomasks for different generations must be conducted on a material layer formed over a wafer, in which those patterns are transferred to the material layer through a photolithographic process. The second preferred embodiment of course does not be restricted only in comparison between different generation's masks and the photomasks in the same generation can be examined by using this method.

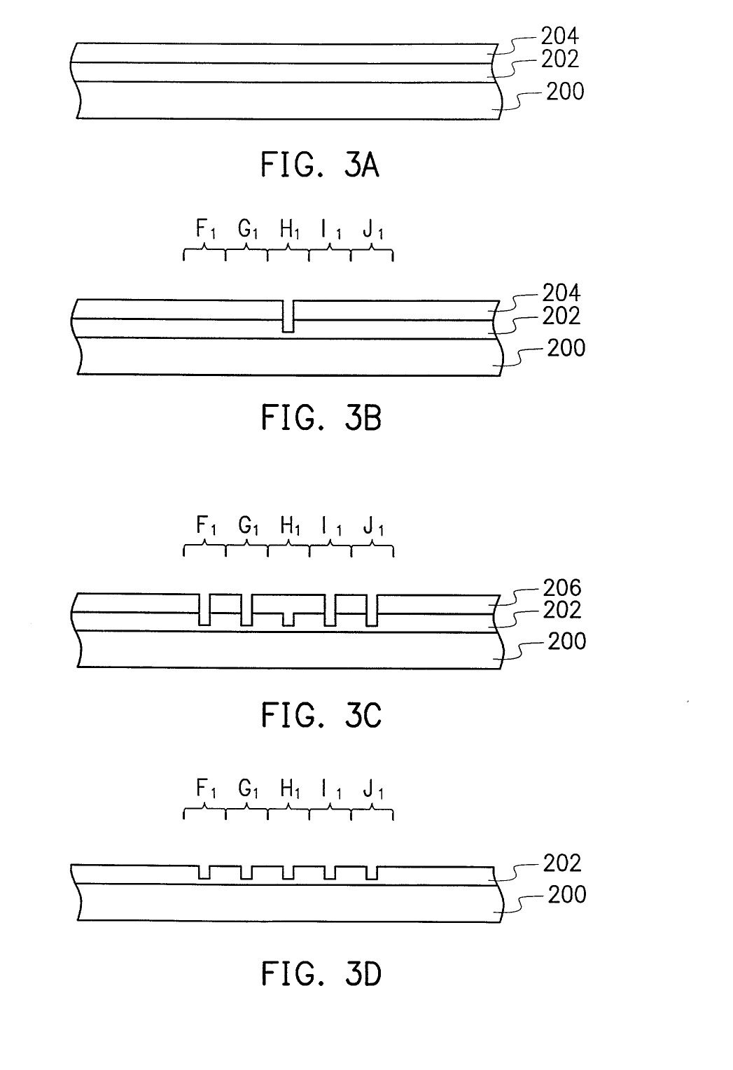

FIG. 2 is a schematic view, illustrating the method for examining a newly-made photomask according to the second preferred embodiment of the present invention. And FIGS. 3A through 3D schematically show, cross-sectional views along line II-II′ shown in FIG. 2, illustrating successive steps according to the second preferred embodiment of the present invention. Referring to FIG. 2 and FIG. 3A, a wafer 200 is provided over which a material layer 202 is formed. The material layer 202, for example, is silicon oxide, silicon nitride, polysilicon, or silicon oxynitride etc. The material layer is formed, for example, by the chemical vapor deposition (CVD). A photoresist layer 204 is formed on the material layer 202.

Referring to FIG. 2 and FIG. 3B, a photolithographic process is performed in order to transfer patterns of a newly-made photomask (DEEP-UV photomask for example) onto the photoresist layer 204. Using the photoresist layer 204 as a mask, the material layer 202 is etched to form pattern areas H1 to H5 of the newly-made photomask on the material layer 202.

Next, referring to FIG. 2 and FIG. 3C, the photoresist layer 204 is removed and another photoresist layer 206 is formed over the wafer 200 again. Patterns of a original photomask (I-line photomask for example) are transferred onto the photoresist layer 206 through a photolithographic process. Using the photoresist layer 206 as a mask, the material layer 202 is etched to form pattern areas of the newly-made photomask on it, wherein pattern areas F1 to F5 and G1 to G5 are formed at the left side of pattern areas H1 to H5, and pattern areas I1 to I5 and J1 to J5 at the right side of pattern areas H1 to H5, respectively.

Referring to FIG. 3D, the photoresist layer 206 is removed then the wafer 200 is placed into a KLA optical inspector for examining the correctness of the newly-made photomask by comparing the patterns of the newly-made photomask with the original photomask. Pattern areas H1 to H5 of the new mask are aligned in the same column, while pattern areas F1 to FS and GI to GS of the original photomask are aligned in columns, respectively, on the left of the column of pattern areas H1 to H5 and pattern areas I1 to I5 and J1 to J5 of the original photomask are aligned in columns, respectively, on the right of the column of pattern areas H1 to H5. Therefore, as shown in FIG. 2, the arrangement of the columns from left to right is pattern areas F1 to F5, G1 to G5, H1 to H5, I1 to I5, and J1 to J5.

Each of the pattern areas described above, such as pattern areas F1 to F5, G1 to G5, H1 to H5, I1 to I5, and J1 to J5, is formed individually in each of the exposure shots of the wafer 200. Therefore, the comparison between different photomasks can also be conducted by an optical inspector in the manner of shot to shot.

As the examination is conducted in a KLA optical inspector, pattern area H1 of the newly-made photomask, for example, is compared with its neighboring pattern areas G1 and I1 of the original photomask to find out whether there are any differences among them. The Pattern area GI is compared with its neighboring pattern areas F1 and H1, while the pattern area I1 is compared with the pattern areas H1 and J1, in order to find out any differences among them. If there are no differences among those compared areas, it can be certified that the newly-made photomask is correct. If any differences are shown, these differences must be further examined in order to ensure whether they are attributed to the pattern of the newly-made photomask.

In addition, if there are any signals revealed repeatedly in the same sites of each of pattern areas H1 to H5, each of repeated signals in the pattern areas must be further examined to recognize whether it is reasonable. Such a reasonable signal is usually caused by the number mark of a photomask. For example, if a DEEP-UV photomask is used, the pattern shown on the wafer, which is transferred from the mask, has an icon “120” on it; and if an I-line photomask is used, the pattern shown on the wafer, which is transferred from the mask, has an icon “320” on it. Therefore, as an examination for a newly-made photomask is conducted, the optical inspector may reveal that the new mask and the original mask are different based on those number marks of photomasks. If the repeated signals are those such as number marks of photomasks, they are reasonable, while if the repeated signals are not those reasonable signals, the newly-made photomask may be abnormal.

In both of the above-described preferred embodiments, the patterns of the new masks are transferred onto the wafer, followed by forming the patterns of the original masks on the wafer beside the new masks' patterns. However, it is of course accepted that the patterns of the original photomasks are transferred onto the wafer to form at least two patterns on it, then the new masks' patterns are formed on the site between the patterns of the original photomasks.

In both of the above-described preferred embodiments, two columns of patterns of the original masks are formed on each side of the column of patterns of the new masks so that five columns of patterns are formed on the wafer. According to such an arrangement, a comparison for the patterns of the new masks and the original masks is performed. It is of course accepted that at least two columns of patterns of the original masks are formed on each side of the column of patterns of the new masks so that at least five columns of patterns are formed on the wafer.

Both of the above-described preferred embodiments are illustrated and demonstrated by KLA optical inspector. If a more powerful optical inspector is available, for the comparison between the patterns of the new masks and the original masks, only one column of patterns of the original photomasks is needed to be formed on each side of the column of patterns of the new masks so that totally three columns of patterns are formed on the wafer; alternatively, the comparison between the patterns, which is selected from any one of the pattern areas (exposure shots) of the new masks on the wafer, and the patterns, which is randomly selected from the pattern areas (exposure shots) of the original masks on the wafer, can be conducted to certify the correctness of the new masks. Referring to FIG. 2, for example, the pattern area H2, randomly selected from pattern areas H1 to H5, is compared with two pattern areas G3 and F4, randomly selected from pattern areas F1 to F5, G1 to G5, I1 to I5, and J1 to J5, to examine whether there are any differences among these pattern areas. If there are no differences among those compared areas, it can be certified that the newly-made photomask is correct. If any differences are shown, they must be further examined in order to ensure whether they are attributed to the pattern of the newly-made photomask for further certifying the newly-made photomask.

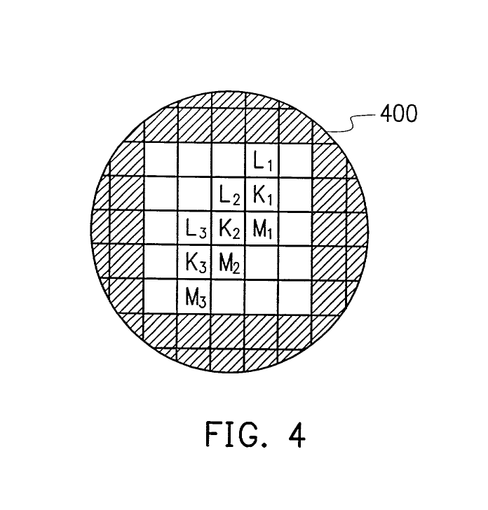

In both of the above-described preferred embodiments of the present invention, the new masks' patterns and the original masks' patterns are aligned in columns, respectively. If a more powerful optical inspector is available, as shown in FIG. 4, after a photoresist layer is formed over a wafer 400, the patterns of the new masks can be exposed in the exposure shots K1 and K3 of the wafer 400 and the patterns of the original masks can be exposed in the exposure shots L1 and L3 on the left of the exposure shots K1 and K3, and in exposure shots M1 and M3 on the right of the exposure shots K1 and K3 of the wafer 400, individually. The wafer 400 is placed in the optical inspector then the comparison between the new masks' patterns and the original masks' patterns is conducted to examine the newly-made photomasks. As shown in FIG. 4, the exposure shots K1 and K3 are aligned with the same diagonal line, while the exposure shots L1 and L3 are aligned with the same diagonal line and are on the top of the arrangement of the exposure shots K1 and K3. By a similar way, the exposure shots M1 and M3 are in alignment with the same diagonal line and are underlying the arrangement of the exposure shots K1 and K3. As an examination is conducted, the pattern of the exposure shot K2, for example, can be compared with the patterns of its vertically neighboring exposure shots L2 and M2 to find out whether there are any differences among them or not. Alternatively, the pattern of the exposure shot K2 can be compared with the patterns of its horizontally neighboring exposure shots L3 and M1 to find out any differences among them. If there are no differences among those compared shots, it can be certified that the newly-made photomask is correct. If any differences are shown, they must be further examined in order to ensure whether they are attributed to the pattern of the newly-made photomask.

According to the descriptions in both of the preferred embodiments of the present invention, the new masks are examined and compared with the original masks (correct masks) by using an optical inspector so that the correctness of the new masks can be certified effectively and rapidly in three days. According to the present invention, the cost can be saved since the correctness of the new masks can be certified quickly before the new masks are subjected to produce the products.

In the present invention, the patterns of the newly-made masks and the original masks are transferred to the same wafer, thus a new photomask can be certified by comparing the new masks' patterns with the original masks' patterns formed on the wafer. In addition, since a comparison is conducted by the optical inspector in the manner of shot to shot, test keys located on the edges of the photomasks can also be compared for examining the correctness of the whole of the masks. Unlike the conventional method that examines the photomask in the manner of die to die, the present invention is more effective and rapid.

Moreover, in the present invention, the comparison is made between a newly-made photomask and an original photomask in different generations as well as in the same generation. For example, an I-line photomask can be used to certify a deep-UV photomask. Similarly, it also can obtain a relatively excellent result as a deep-UV photomask is used to examine an I-line photomask.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for certifying a newly-made photomask, comprising the steps of:
providing a wafer;
transferring a pattern of a newly-made photomask onto the wafer to form a first pattern thereon;
transferring a pattern of an original photomask onto the wafer to form a second pattern thereon; and
comparing the first pattern with the second pattern so as to certify the correctness of the newly-made photomask.

2. The method of claim 1, wherein the pattern of the newly-made photomask is transferred onto a photoresist layer on the wafer and the pattern of the original photomask is transferred onto the photoresist layer on the wafer.

3. The method of claim 1, wherein the pattern of the newly-made photomask is transferred onto a first exposure shot on the wafer and the pattern of the original photomask is transferred onto a second exposure shot on the wafer.

4. The method of claim 1, wherein the pattern of the newly-made photomask is transferred onto a first exposure shot on the wafer and the pattern of the original photomask is transferred onto two second exposure shot on the wafer, wherein the first exposure shot is located between the second exposure shots.

5. The method of claim 1, wherein the pattern of the newly-made photomask is respectively transferred onto a plurality of first exposure shots on the wafer and the pattern of the original photomask is respectively transferred onto a plurality of second exposure shots and onto a plurality of third exposure shots on the wafer, wherein the first exposure shots, the second exposure shots, and the third exposure shots are aligned in columns, respectively.

6. The method of claim 1, wherein the newly-made photomask and the original photomask are the same generation.

7. The method of claim 1, wherein the newly-made photomask and the original photomask are different generations.

8. A method for certifying a newly-made photomask, comprising the steps of providing a wafer;
forming a material layer over the wafer;
forming a first photoresist layer on the material layer;
transferring a pattern of the newly-made photomask onto the first photoresist layer by performing an exposure and development step;
etching the material layer to form a first pattern therein using the first photoresist layer as a mask;
removing the first photoresist layer;
forming a second photoresist layer over the wafer;
transferring a pattern of an original photomask onto the second photoresist layer by performing an exposure and development step;
etching the material layer to form a second pattern using the second photoresist layer as a mask;
removing the second photoresist layer; and
comparing the first pattern with the second pattern so as to certify the correctness of the newly-made photomask.

9. The method of claim 8, wherein the newly-made photomask and the original photomask are different generations.

10. The method of claim 8, wherein the newly-made photomask and the original photomask are the same generation.

11. The method of claim 8, wherein the pattern of the newly-made photomask is transferred onto a first exposure shot of the material layer and the pattern of the original photomask is transferred onto a second exposure shot of the material layer.

12. The method of claim 8, wherein the pattern of the newly-made photomask is transferred onto a first exposure shot on the material layer and the pattern of the original photomask is transferred onto two second exposure shot on the material layer, wherein the first exposure shot is located between the second exposure shots.

13. The method of claim 8, wherein the pattern of the newly-made photomask is respectively transferred onto a plurality of first exposure shots on the material layer and the pattern of the original photomask is respectively transferred onto a plurality of second exposure shots and onto a plurality of third exposure shots on the material layer, wherein the first exposure shots, the second exposure shots, and the third exposure shots are aligned in columns, respectively.

14. A method for certifying a newly-made photomask, comprising the steps of:
providing a wafer having a plurality of first exposure shots, a plurality of second exposure shots and a plurality of third exposure shots, wherein the first exposure shots, the second exposure shots and the third exposure shots are aligned in columns, respectively;
transferring a pattern of the newly-made photomask respectively onto the first exposure shots of the wafer to form a plurality of first patterns;
transferring a pattern of the original photomask respectively onto the second exposure shots and onto the third exposure shots of the wafer to form a plurality of second patterns; and
comparing the first patterns with the second patterns so as to certify the correctness of the newly-made photomask.

15. The method of claim 14, wherein the newly-made photomask and the original photomask are different generations.

16. The method of claim 14, wherein the newly-made photomask and the original photomask are the same generation.

17. The method of claim 15, wherein the pattern of the newly-made photomask is transferred onto a material layer of the wafer and the pattern of the original photomask is transferred onto the material layer of the wafer.

18. The method of claim 16, wherein the pattern of the newly-made photomask is transferred onto a photoresist layer of the wafer and the pattern of the original photomask is transferred onto the photoresist layer of the wafer.

19. The method of claim 14, wherein the step of comparing the first patterns with the second patterns is performed by comparing the first exposure shots with the second and third exposure shots.

20. The method of claim 14, wherein the step of comparing the first patterns with the second patterns is performed by comparing one of the first patterns selected from the first exposure shots with two of the second patterns selected respectively from the second exposure shots and the third exposure shots.
